(19) United States
(12) Patent Application Publication
(10) Pub. No.: US 2014/0030824 A1
(43) Pub. Date: Jan. 30, 2014

(54) SEMICONDUCTOR DEVICE HAVING CAPACITOR WITH CAPACITOR FILM HELD BETWEEN LOWER ELECTRODE AND UPPER ELECTRODE

(71) Applicant: FUJITSU SEMICONDUCTOR LIMITED, Yokohama-shi (JP)

(72) Inventor: Wensheng Wang, Kawasaki (JP)

(73) Assignee: FUJITSU SEMICONDUCTOR LIMITED, Yokohama-shi (JP)

(21) Appl. No.: 14/041,783

(22) Filed: Sep. 30, 2013

Related U.S. Application Data
(62) Division of application No. 12/240,140, filed on Sep. 29, 2008.
Application No. 12/240,140 is a continuation of application No. PCT/JP2006/306679, filed on Mar. 30, 2006.

(51) Int. Cl. H01L 49/02

(52) U.S. Cl. CPC H01L 28/40
USPC 438/3

(57) ABSTRACT

A ferroelectric memory is constituted to comprise a capacitor being formed above a semiconductor substrate (61) and having a ferroelectric film (78) held between a lower electrode (77) and an upper electrode (79), a W plug (72b) electrically connected on its upper surface with the lower electrode (77), and a protective film (76) formed between the W plug (72b) and the lower electrode (77) and made of at least any one kind out of a conductive oxide, a conductive nitride, and a conductive oxynitride. The protective film (76) prevents an orientation of the lower electrode (77) from depending on the W plug (72b), thereby making the orientation of the lower electrode (77) uniform. Accordingly, it is possible to make an orientation of the ferroelectric film (78) to be formed on the lower electrode (77) uniform, which enables to improve an electric characteristic of the ferroelectric capacitor.

### CROSS-REFERENCE TO RELATED APPLICATIONS

This application is a divisional of U.S. application Ser. No. 12/240,140, filed on Sep. 29, 2008, which is a Continuation of International Application No. PCT/JP2006/306679 filed on Mar. 30, 2006, designating the United States of America, the entire contents of which are incorporated herein by reference.

### FIELD

The present embodiment relates to a structure of a semiconductor device having a ferroelectric capacitor and a manufacturing method thereof.

### BACKGROUND

In recent years, with development of digital technology, there has been a growing trend to process or store high-volume data at a high speed. Therefore, enhancement of integration density and performance of semiconductor devices which are used in electronic equipment are required.

Thus, with regard to a semiconductor memory device, in order to realize high integration density of, for example, a DRAM, the technique of using a ferroelectric material and a high dielectric material as a capacity insulating film of a capacitor element (capacitor) configuring the DRAM, instead of a silicon oxide and a silicon nitride which have been conventionally used, starts to be researched and developed.

Further, in order to realize a nonvolatile RAM capable of a write operation and a read operation at a lower voltage at a high speed, the technique of using a ferroelectric substance having a spontaneous polarization characteristic as a capacity insulating film is actively researched and developed. Such a semiconductor memory device is called a ferroelectric memory (FeRAM: Ferroelectric Random Access Memory).

A ferroelectric memory includes a ferroelectric capacitor which is configured by a ferroelectric film being held between a pair of electrodes as a capacity insulating film. In the ferroelectric memory, information is stored by using a hysteresis characteristic of the ferroelectric film.

The ferroelectric film causes polarization in accordance with an applied voltage between the electrodes, and has the spontaneous polarization characteristic even after the applied voltage is removed. Further, if the polarity of the applied voltage is reversed, the polarity of the spontaneous polarization of the ferroelectric film is also reversed. Accordingly, if the spontaneous polarization is detected, the information can be read. A ferroelectric memory operates at a low voltage as compared with a flash memory, and is capable of a write operation at a high speed with a reduced power.

Recently, in a ferroelectric memory, higher integration density and higher performance have been also required as in the other semiconductor devices, and further miniaturization of memory cells will be required in future. It is known that adoption of the stack type structure in which electrical connection of the upper electrode of the ferroelectric capacitor is taken from above and electrical connection of the lower electrode is taken from below, instead of the planar type structure in which electrical connections of the upper electrode and the lower electrode of the ferroelectric capacitor are taken from above, is effective for miniaturization of the memory cells.

In a general stack type ferroelectric memory, the ferroelectric capacitor is formed on a conductive plug formed right above a drain of a transistor which configures the memory cell.
Patent Document 1: Japanese Patent Application Laid-open No. 2004-311868

However, the conventional ferroelectric memory has a problem that it is difficult to enhance an electric characteristic of the ferroelectric capacitor because of a nonuniformity of an orientation of a ferroelectric film (capacitor film) in the ferroelectric capacitor.

In this case, there is an idea of uniformly forming the capacitor film. However, the ferroelectric film being the capacitor film of the ferroelectric capacitor is likely to be influenced by a heat treatment and by a layer contacted thereto, so that it is very difficult to form the film while making its orientation uniform.

### SUMMARY

A semiconductor device, including: a capacitor formed above a semiconductor substrate and having a capacitor film held between a lower electrode and an upper electrode; a conductive plug electrically connected on its upper surface with said lower electrode; and a protective film being self-oriented formed between said conductive plug and said lower electrode and made of at least any one kind out of a conductive oxide, a conductive nitride, and a conductive oxynitride.

Additional objects and advantages of the invention will be set forth in part in the description which follows, and in part will be obvious from the description, or may be learned by practice of the invention. The object and advantages of the invention will be realized and attained by means of the elements and combinations particularly pointed out in the appended claims.

It is to be understood that both the foregoing general description and the following detailed description are exemplary and explanatory only and are not restrictive of the invention, as claimed.

### BRIEF DESCRIPTION OF DRAWINGS

FIG. 1 is a schematic view showing a ferroelectric memory (semiconductor device);

FIG. 2A is a schematic sectional view showing a manufacturing method of a ferroelectric memory according to an embodiment;

FIG. 2B is a schematic sectional view showing the manufacturing method of the ferroelectric memory according to the embodiment;

FIG. 2C is a schematic sectional view showing the manufacturing method of the ferroelectric memory according to the embodiment;

FIG. 3A is a schematic sectional view showing the manufacturing method of the ferroelectric memory according to the embodiment;

FIG. 3B is a schematic sectional view showing the manufacturing method of the ferroelectric memory according to the embodiment;

FIG. 3C is a schematic sectional view showing the manufacturing method of the ferroelectric memory according to the embodiment;

FIG. 4A is a schematic sectional view showing the manufacturing method of the ferroelectric memory according to the embodiment;

FIG. 4B is a schematic sectional view showing the manufacturing method of the ferroelectric memory according to the embodiment;

FIG. 4C is a schematic sectional view showing the manufacturing method of the ferroelectric memory according to the embodiment;

FIG. 5A is a schematic sectional view showing the manufacturing method of the ferroelectric memory according to the embodiment;

FIG. 5B is a schematic sectional view showing the manufacturing method of the ferroelectric memory according to the embodiment;

FIG. 5C is a schematic sectional view showing the manufacturing method of the ferroelectric memory according to the embodiment;

FIG. 6A is a schematic sectional view showing the manufacturing method of the ferroelectric memory according to the embodiment;

FIG. 6B is a schematic sectional view showing the manufacturing method of the ferroelectric memory according to the embodiment;

FIG. 6C is a schematic sectional view showing the manufacturing method of the ferroelectric memory according to the embodiment;

FIG. 7A is a schematic sectional view showing the manufacturing method of the ferroelectric memory according to the embodiment;

FIG. 7B is a schematic sectional view showing the manufacturing method of the ferroelectric memory according to the embodiment;

FIG. 7C is a schematic sectional view showing the manufacturing method of the ferroelectric memory according to the embodiment;

FIG. 8A is a schematic sectional view showing the manufacturing method of the ferroelectric memory according to the embodiment;

FIG. 8B is a schematic sectional view showing the manufacturing method of the ferroelectric memory according to the embodiment;

FIG. 8C is a schematic sectional view showing the manufacturing method of the ferroelectric memory according to the embodiment;

FIG. 9A is a schematic sectional view showing the manufacturing method of the ferroelectric memory according to the embodiment;

FIG. 9B is a schematic sectional view showing the manufacturing method of the ferroelectric memory according to the embodiment;

FIG. 10A is a schematic sectional view showing a manufacturing method of a ferroelectric memory according to a modified example 1 of the embodiment;

FIG. 10B is a schematic sectional view showing the manufacturing method of the ferroelectric memory according to the modified example 1 of the embodiment;

FIG. 11A is a schematic sectional view showing a manufacturing method of a ferroelectric memory according to a modified example 2 of the embodiment;

FIG. 11B is a schematic sectional view showing the manufacturing method of the ferroelectric memory according to the modified example 2 of the embodiment;

FIG. 11C is a schematic sectional view showing the manufacturing method of the ferroelectric memory according to the modified example 2 of the embodiment;

FIG. 12A is a schematic sectional view showing the manufacturing method of the ferroelectric memory according to the modified example 2 of the embodiment;

FIG. 12B is a schematic sectional view showing the manufacturing method of the ferroelectric memory according to the modified example 2 of the embodiment;

FIG. 12C is a schematic sectional view showing the manufacturing method of the ferroelectric memory according to the modified example 2 of the embodiment;

FIG. 13A is a schematic sectional view showing the manufacturing method of the ferroelectric memory according to the modified example 2 of the embodiment;

FIG. 13B is a schematic sectional view showing the manufacturing method of the ferroelectric memory according to the modified example 2 of the embodiment;

FIG. 13C is a schematic sectional view showing the manufacturing method of the ferroelectric memory according to the modified example 2 of the embodiment;

FIG. 14A is a schematic sectional view showing the manufacturing method of the ferroelectric memory according to the modified example 2 of the embodiment;

FIG. 14B is a schematic sectional view showing the manufacturing method of the ferroelectric memory according to the modified example 2 of the embodiment;

FIG. 14C is a schematic sectional view showing the manufacturing method of the ferroelectric memory according to the modified example 2 of the embodiment;

FIG. 15A is a schematic sectional view showing the manufacturing method of the ferroelectric memory according to the modified example 2 of the embodiment;

FIG. 15B is a schematic sectional view showing the manufacturing method of the ferroelectric memory according to the modified example 2 of the embodiment;

FIG. 15C is a schematic sectional view showing the manufacturing method of the ferroelectric memory according to the modified example 2 of the embodiment;

FIG. 16A is a schematic sectional view showing the manufacturing method of the ferroelectric memory according to the modified example 2 of the embodiment;

FIG. 16B is a schematic sectional view showing the manufacturing method of the ferroelectric memory according to the modified example 2 of the embodiment;

FIG. 17A is a characteristic diagram showing an integrated intensity of orientation in a crystal plane (111) of a ferroelectric film (PZT film) of a ferroelectric memory according to the embodiment and that of a ferroelectric memory according to a comparative example;

FIG. 17B is a characteristic diagram showing a ratio of orientation in a crystal plane (222) of the ferroelectric film (PZT film) of the ferroelectric memory according to the embodiment and that of the ferroelectric memory according to the comparative example;

FIG. 18A is a characteristic diagram of a rocking curve of the crystal plane (111) of the ferroelectric film (PZT film) of the ferroelectric memory according to the embodiment and that of the ferroelectric memory according to the comparative example; and

FIG. 18B is a characteristic diagram of a FWHM (Full width half maximum) of the rocking curve of the crystal plane (111) of the ferroelectric film (PZT film) of the ferroelectric memory according to the embodiment and that of the ferroelectric memory according to the comparative example.

### DESCRIPTION OF EMBODIMENTS

As a result of repeating studies in order to investigate the cause of nonuniformity of an orientation of a ferroelectric film in a ferroelectric capacitor, the present inventor has found that it is due to a nonuniformity of an orientation of a lower electrode formed below the ferroelectric film. Further, the present inventor has also found that the orientation of the lower electrode is influenced by the conductive plug to be formed below the lower electrode, which is a cause of the nonuniformity of the orientation.

From these points, the present inventor considered that in order to make the orientation of the ferroelectric film uniform, it is necessary to control by eliminating the influence of the conductive plug so that the orientation of the lower electrode becomes uniform. The present inventor has reached the mode of the invention described as follows based on these views.

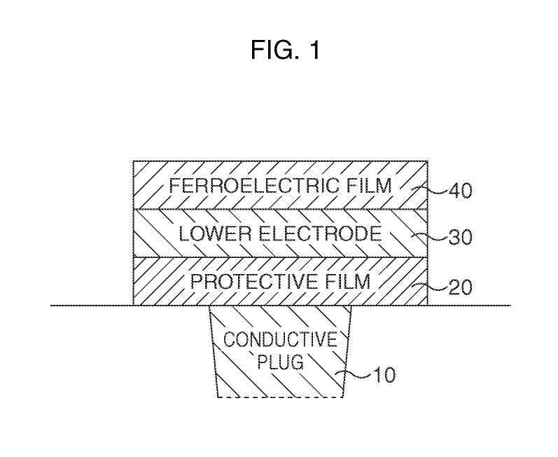

FIG. 1 is a schematic view showing a ferroelectric memory (semiconductor device).

In the present invention, a protective film 20 which eliminates an influence of crystallinity and the like of a conductive plug 10 and protects orientation of a lower electrode 30 is formed between the lower electrode 30 and the conductive plug 10 of a ferroelectric capacitor, as shown in FIG. 1. The protective film 20 is formed as a self-oriented film formed of at least any one kind out of a conductive oxide, a conductive nitride, and a conductive oxynitride. Here, the “self-oriented film” is a film which is oriented based on its own characteristic without being influenced by a film contacted thereto.

The protective film 20 is formed without being affected by a film positioned right below it (conductive plug 10 in an example shown in FIG. 1), and by providing this protective film 20, it is possible to form the lower electrode 30 which is not influenced by the crystallinity and the like of the conductive plug 10 and thus has a uniform orientation. Accordingly, it is possible to make the ferroelectric film 40 to be formed on the lower electrode 30 to be a film whose orientation is uniform, resulting that an electric characteristic of the ferroelectric capacitor can be enhanced.

Hereinafter, an example of a concrete forming method of the protective film 20 will be explained.

First, above the conductive plug 10, an amorphous film made of at least any one kind out of a conductive oxide, a conductive nitride, and a conductive oxynitride is formed. Next, after a lower electrode film to be the lower electrode 30 is formed above the amorphous film, a heat treatment is performed to crystallize the amorphous film, thereby forming the protective film 20 being self-oriented and having an aligned crystal orientation. As described above, by forming the amorphous film above the conductive plug 10, the protective film 20 which does not depend on the crystallinity of the conductive plug 10 can be formed.

Note that in Patent Document 1, the formation of an amorphous metal film on top of the conductive plug is described. On the contrary, in the present invention, an amorphous film formed of, not the metal, but at least any one kind out of a conductive oxide, a conductive nitride, and a conductive oxynitride is used to form the protective film 20, so that the present invention and the invention disclosed in Patent Document 1 are apparently separate inventions. Further, in general, to apply a conductive oxide film, a conductive nitride film, or a conductive oxynitride film as a film to be formed on the conductive plug provides a versatility and an ease of use compared to a case where the amorphous metal film is applied.

Further, there is a concern that, according to Patent Document 1, since the amorphous metal film is not a precious metal film, it becomes an insulator when being oxidized, which may impede an electric connection between the lower electrode and the conductive plug. For this reason, the amorphous metal film in Patent Document 1 has to be surely formed on a lower layer of an oxidation preventing film for the conductive plug (namely, right above the conductive plug). On the contrary, the protective film 20 formed of a conductive oxide, or the like never becomes the insulator, so that it can be formed, not only right above the conductive plug, but also on any places without limitations as long as it is formed between the lower electrode and the conductive plug. Further, in a case, it also becomes possible to form the protective film 20 right below the lower electrode 30 which is the most effective place in terms of making the orientation of the lower electrode 30 uniform. For instance, when the aforementioned oxidation preventing film is formed on the conductive plug, the protective film 20 is formed above the oxidation preventing film. In this case, if an annealing treatment is performed after the formation of the lower electrode 30, an amorphous state conductive oxide or the like to be the protective film 20 returns to, for example, the precious metal or the like, which enables to make a crystal plane of the protective film 20 to be uniformly oriented along, for instance, a (111) plane, resulting that a crystal plane of the lower electrode 30 can be uniformly oriented along, for instance, a (111) plane.

Hereinafter, an embodiment will be described. It should be noted that a sectional structure of each memory cell of the ferroelectric memory will be described together with its manufacturing method here for convenience.

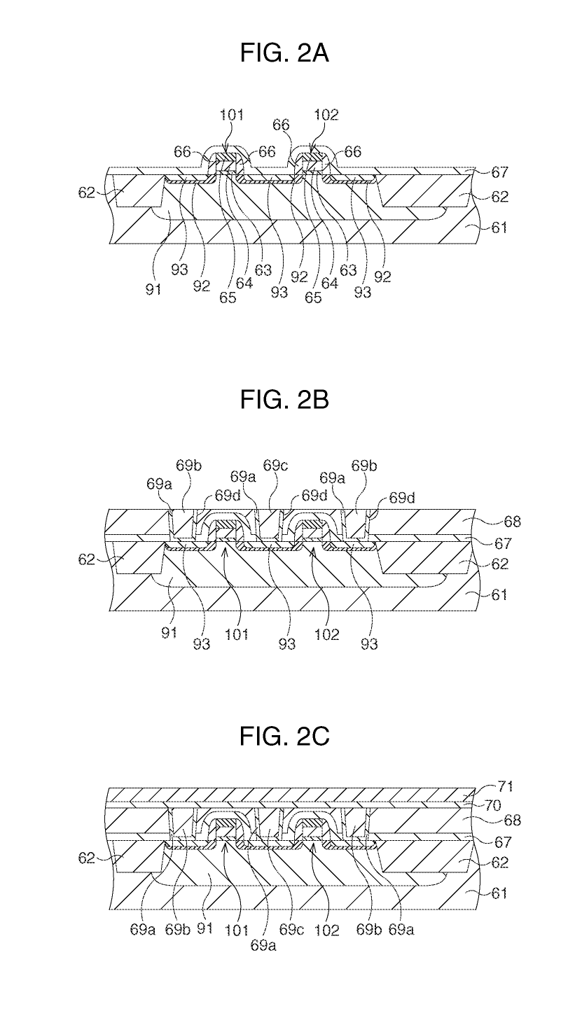

FIGS. 2A to 9B are schematic sectional views showing a manufacturing method of a ferroelectric memory (semiconductor device) according to the embodiment.

First, as shown in FIG. 2A, an element isolation structure 62 and, for example, a p-well 91 are formed in a semiconductor substrate 61, and further, above the semiconductor substrate 61, MOSFETs 101 and 102 are formed, and, for example, an SiON film (silicon oxynitride film) 67 which covers each of the MOSFETs is formed.

More specifically, first, the element isolation structure, the element isolation structure 62 by an STI (Shallow Trench Isolation) method in this case is formed in the semiconductor substrate 61 such as an Si substrate, and an element formation region is defined. In this embodiment, the element isolation structure is formed by the STI method, but the element isolation structure may be formed by, for example, an LOCOS (Local Oxidation of Silicon) method.

Subsequently, for example, boron (B) is ion-implanted in the surface of the element formation region of the semiconductor substrate 61 under the conditions of, for example, energy of 300 keV and an dose amount of 3.0×10¹³ cm⁻², and the p-well 91 is formed. Subsequently, a silicon oxide film of a thickness of about 3 nm is formed above the semiconductor substrate 61 by, for example, a thermal oxidation method. Subsequently, a polycrystalline silicon film of a thickness of about 180 nm is formed on the silicon oxide film by a CVD method. Subsequently, patterning is performed, by which the polycrystalline silicon film and the silicon oxide film are left in only the element formation region, and gate insulating films 63 constituted of the silicon oxide film, and gate electrodes 64 constituted of the polycrystalline silicon film are formed. The gate electrodes 64 configure part of a word line.

Subsequently, with the gate electrodes 64 used as masks, phosphor (P), for example, is ion-implanted in the surface of the semiconductor substrate 61 under the conditions of, for example, energy of 13 keV, a dose amount of 5.0×10¹⁴ cm⁻², and an n⁻-type low concentration diffusion layer 92 is formed. Subsequently, after an SiO₂ film of a thickness of about 300 nm is formed on the entire surface by a CVD method, anisotropic etching is performed, and the SiO₂ film is left only on side walls of the gate electrodes 64 to form side walls 66.

Subsequently, with the gate electrodes 64 and the side walls 66 as masks, arsenide (As), for example, is ion-implanted in the surface of the semiconductor substrate 61 under the conditions of, for example, energy of 10 keV and a dose amount of 5.0×10¹⁴ cm⁻², and an n⁺-type high concentration diffusion layer 93 is formed.

Subsequently, for example, a Ti film is deposited on the entire surface by, for example, a sputtering method. Thereafter, by performing heat treatment at a temperature of 400° C. to 900° C., silicide formation reaction occurs between the polycrystalline silicon film of the gate electrodes 64 and the Ti film, and a silicide layer 65 is formed on top surfaces of the gate electrodes 64. Thereafter, the unreacted Ti film is removed by using hydrofluoric acid or the like. Thereby, the MOSFETs 101 and 102 each including the gate insulating film 63, the gate electrode 64, the silicide layer 65, the side walls 66 which are formed above the semiconductor substrate 61, and a source/drain diffusion layer, which formed beneath the surface of the semiconductor substrate 61, constituted of the low concentration diffusion layer 92 and the high concentration diffusion layer 93 are formed. In the present embodiment, formation of the n-channel type MOSFET is described as an example, but, a p-channel type MOSFET may be formed. Subsequently, the SiON film 67 of a thickness of about 200 nm is formed on the entire surface by a plasma CVD method.

Next, as shown in FIG. 2B, an interlayer insulating film 68, a glue film 69a and W plugs 69b and 69c are formed.

More specifically, first, by a plasma CVD method using TEOS (tetraethyl orthosilicate) gas, a silicon oxide film of a thickness of about 1000 nm is deposited on the SiON film 67, thereafter, this is flattened by a CMP method, and the interlayer insulating film 68 constituted of the silicon oxide film is formed with a thickness of about 700 nm.

Subsequently, via holes 69d which reach the high concentration diffusion layer 93 of the respective MOSFETs are each formed with a diameter of, for example, about 0.25 μm in the interlayer insulating film 68 and the SiON film 67. Thereafter, a Ti film of a thickness of about 30 nm and a TiN film of a thickness of about 20 nm are continuously stacked on the entire surface by, for example, a sputtering method.

Subsequently, by a CVD method, a W film of a thickness sufficient to fill each of the via holes 69d is further deposited, and thereafter, by performing flattening by polishing the W film, TiN film and Ti film until the surface of the interlayer insulating film 68 is exposed by a CMP method, the glue film 69a constituted of the Ti film and the TiN film, and the W plugs 69b and 69c are formed in the via holes 69d. The W plugs 69b and 69c are formed with a thickness of about 300 nm on the flat surface of the interlayer insulating film 68. Here, the W plug 69b connects to one of the source/drain diffusion layers of each of the MOSFETs and the W plug 69c connects to the other one.

Next, as shown in FIG. 2C, a silicon oxynitride film (SiON film) 70 of a thickness of about 130 nm is formed on the entire surface by a plasma CVD method. The silicon oxynitride film 70 becomes an oxidation preventing film which prevents oxidation of the W plugs 69b and 69c. Here, instead of the SiON film, for example, a silicon nitride film and an alumina film (Al₂O₃ film) may be formed. Subsequently, an interlayer insulating film 71 constituted of a silicon oxide film of a thickness of about 300 nm is formed on the silicon oxynitride film 70 by a plasma CVD method with TEOS as a raw material.

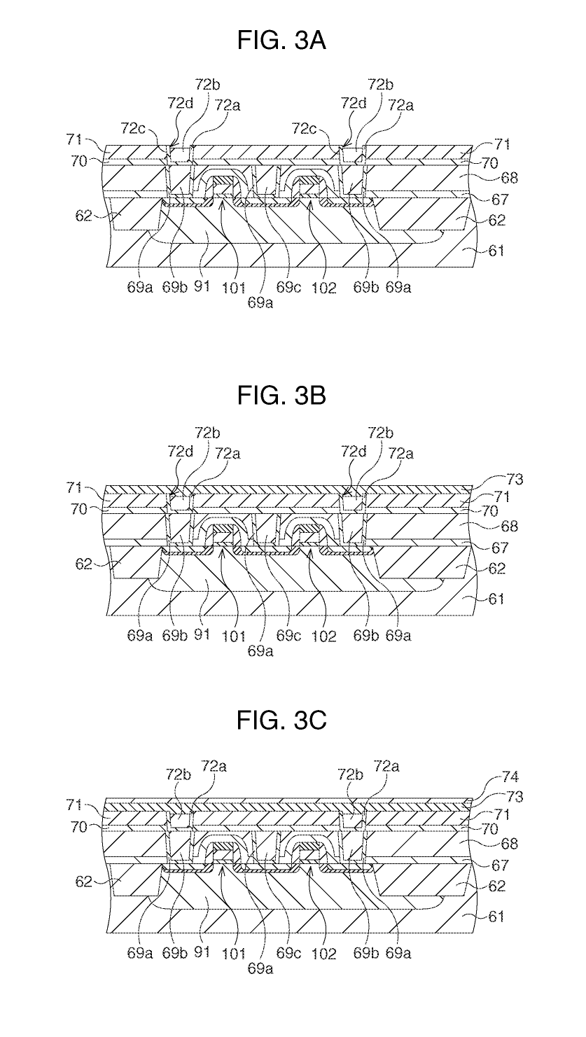

Next, as shown in FIG. 3A, a glue film 72a and W plugs 72b are formed.

More specifically, first, via holes 72c in which the surfaces of the W plugs 69b are exposed are formed in the interlayer insulating film 71 and the silicon oxynitride film 70, each with a diameter of, for example, about 0.25 μm. Thereafter, a Ti film of a thickness of about 30 nm and a TiN film of a thickness of about 20 nm are successively stacked on the entire surface by a sputtering method.

Subsequently, after a W film of a thickness sufficient to fill the respective via holes 72c is deposited by a CVD method, the W film, the TiN film and the Ti film are polished by a CMP method until the surface of the interlayer insulating film 71 is exposed to perform flattening, whereby the glue films 72a and the W plugs 72d are formed in the via holes 72c.

In the CMP method in this case, slurry that makes the polishing speed of the W film, TiN film and Ti film which are the objects to be polished higher than the interlayer insulating film 71 which is the base, for example, trade name SSW2000 made by Cabot Microelectronics Corporation is used. In this case, in order not to leave an unpolished portion on the interlayer insulating film 71, in the polishing by the CMP method, the polishing amount is set to be larger than the total film thickness of the W film, TiN film and Ti film. As a result, as shown in FIG. 3A, the position of the top surface of the W plug 72b becomes lower than the position of the top surface of the interlayer insulating film 71, and a recessed part (hereinafter, the recessed part will be called “recess”) 72d is formed. The depth of the recess 72d is about 20 nm to 50 nm, and is typically about 50 nm.

Thereafter, the surface of the interlayer insulating film 71 is plasma-processed in the atmosphere of NH₃ (ammonia) gas, and an NH group is caused to bond to oxygen atoms on the surface of the interlayer insulating film 71. The plasma processing using ammonia gas is performed by using, for example, a parallel plate type plasma processing apparatus having counter electrodes at a position separated by about 9 mm (350 mils) with respect to the semiconductor substrate 61, by supplying ammonia gas at a flow rate of about 350 sccm into a processing vessel held at a pressure of about 266 Pa (2.0 Torr) and at a substrate temperature of about 400° C., and supplying a high frequency of about 13.56 MHz with a power of about 100 W to the semiconductor substrate 61 and a high frequency of about 350 kHz with a power of about 55 W to the above-described counter electrodes, respectively for about 60 seconds.

Next, as shown in FIG. 3B, a TiN (titanium nitride) film 73, which fills the recess 72d and covers the top of the interlayer insulating film 71, is formed.

More specifically, first, by using, for example, a sputtering device with the distance between the semiconductor substrate 61 and the target set about 60 mm, a Ti film of a thickness of about 100 nm is formed by a sputtering method of supplying a DC power of about 2.6 kW for about seven seconds at a substrate temperature of about 20° C. under an Ar atmosphere at a pressure of about 0.15 Pa (1.1×10⁻³ Torr). Since the Ti film is formed on the interlayer insulating film 71 which is plasma-processed by using ammonia gas, the Ti atoms can freely move on the surface of the interlayer insulating film 71 without being captured by the oxygen atoms of the interlayer insulating film 71, and as a result, the Ti film becomes a self-organized Ti film in which the crystal plane is oriented along a (002) plane.

Subsequently, by applying heat treatment by RTA (Rapid Thermal Annealing) at a temperature of about 650° C. for a time of about 60 seconds to the Ti film in an nitrogen atmosphere, the TiN film 73 of a thickness of about 100 nm to be a base conductive film is formed. Here, in the TiN film 73, its crystal plane is oriented along a (111) plane. The thickness of the base conductive film is preferably about 100 nm to 300 nm, and is set at about 100 nm in the present embodiment. The base conductive film is not limited to the TiN film, and for example, a tungsten (W) film, a silicon (SiO₂) film and a copper (Cu) film can be used as the base conductive film.

In this state, in the TiN film 73, recessed portions are formed on its top surface by reflecting the shape of the recesses 72d, and this becomes the cause of degrading the crystallinity of the ferroelectric film to be formed above the TiN film 73 (orientation of the ferroelectric film becomes non-uniform). Thus, in this embodiment, as shown in FIG. 3B, the top surface of the TiN film 73 is polished and flattened by a CMP method, and the above-described recessed portions are removed. The slurry which is used in the CMP method is not especially limited, but, in the present embodiment, the aforementioned trade name SSW2000 made by Cabot Microelectronics Corporation is used.

A variation occurs in the thickness of the flattened TiN film 73 on the interlayer insulating film 71 within the plane of the semiconductor substrate 61 and among a plurality of semiconductor substrates due to a polishing error. In consideration of the variation, in the present embodiment, the polishing time by the CMP method is controlled, and the target value of the thickness after flattening is set at about 50 nm to 100 nm. In the present embodiment, the thickness of the flattened TiN film 73 on the interlayer insulating film 71 is set at about 50 nm.

Further, after flattening by the CMP method is applied to the TiN film 73, the crystal in the vicinity of the top surface of the TiN film 73 is in a distorted state by polishing. If the lower electrode of the ferroelectric capacitor formed above is influenced by the distortion, crystallinity of the lower electrode degrades (orientation of the lower electrode becomes non-uniform), and ultimately, the crystallinity of the ferroelectric film formed thereon degrades (orientation of the ferroelectric film becomes non-uniform). In order to avoid such a trouble, in the present embodiment, plasma processing is applied to the top surface of the TiN film 73 in an NH₃ (ammonia) gas atmosphere, thereby eliminating the distortion of the crystal of the TiN film 73.

Next, as shown in FIG. 3C, a Ti film 74 of a thickness of about 20 nm is formed as a crystalline conductive adhesive film, on the TiN film 73 in which the distortion of the crystal is eliminated, by a sputtering method. Subsequently, by performing heat treatment by RTA at a temperature of about 650° C. for a time of about 60 seconds in a nitrogen atmosphere, the TiN film 73 with its crystal plane oriented along a (111) plane is formed. The crystalline conductive adhesive film is not limited to the TiN film, and, for example, a thin precious metal film such as an Ir film and a Pt film of a thickness of about 10 nm can be used.

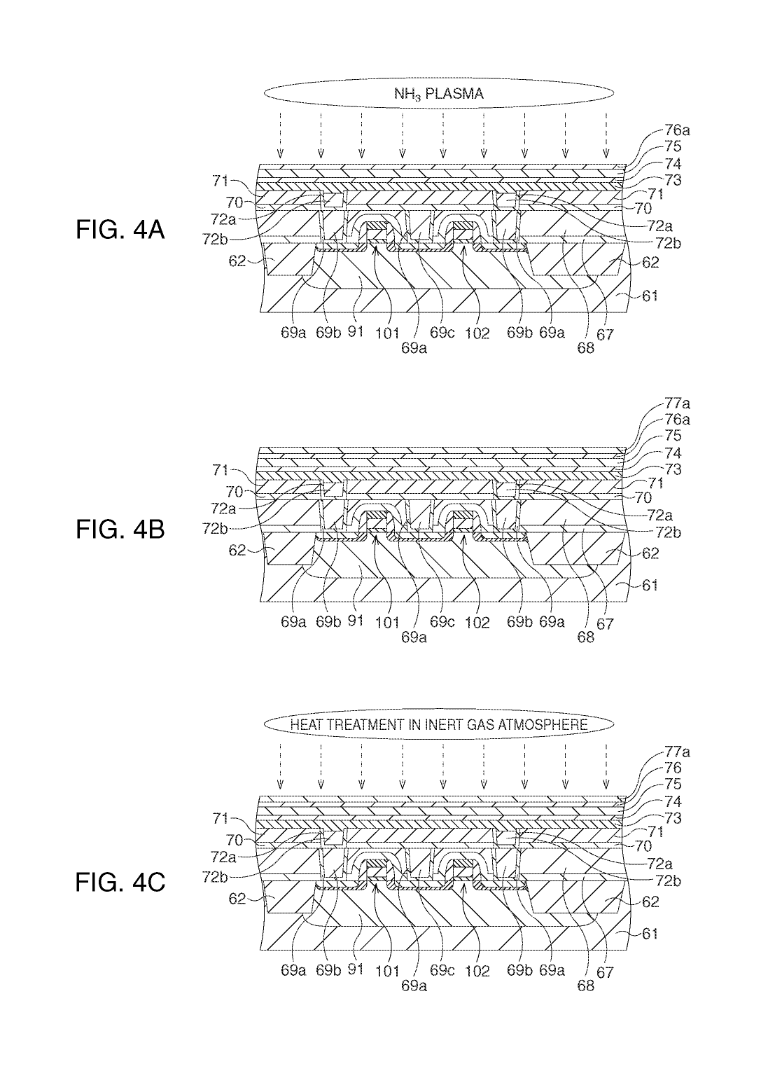

Next, as shown in FIG. 4A, an oxidation preventing film 75 and an amorphous film 76a are formed on the Ti film 74. Here, the oxidation preventing film 75 is a film for preventing oxidation of the W plugs 72b.

More specifically, in the present embodiment, as the oxidation preventing film 75, a TiAlN film of a thickness of about 100 nm is formed on the Ti film 74 by a reactive sputtering method. For example, the reactive sputtering method in this case is carried out by using Ti and Al as an alloyed target, under the conditions of a pressure of about 253.3 Pa (1.9 Torr), a substrate temperature of 400° C. and a power of 1.0 kW in a mixture atmosphere in which Ar gas at a flow rate of about 40 sccm and nitrogen (N₂) gas at a flow rate of about 10 sccm are supplied.

In the present embodiment, the example in which the film constituted of TiAlN is applied as the oxidation preventing film 75 is shown, but, the present invention is not limited to this, and a film including, for example, Ir or Ru can be applied.

Next, the amorphous film 76a having a self-orientation and being made of at least any one kind out of a conductive oxide, a conductive nitride, and a conductive oxynitride is formed on the oxidation preventing film 75. Here, “to have a self-orientation” means that it is possible to realize a self-orientation with a help of a physical process such as a heat treatment. The amorphous film 76a has a function of resetting the crystallinity of the oxidation preventing film 75 and the lower layer films located therebelow.

When the amorphous film 76a applies a conductive oxide film, it is formed by a film including at least any one kind out of PtOx, IrOx, RuOx, and PdOx. Further, when the amorphous film 76a applies a conductive nitride film, it is formed by a film including at least any one kind out of TiN, TiAlN, TaN and TaAlN. Furthermore, when the amorphous film 76a applies a conductive oxynitride film, it is formed by a film including, for example, TiAlON.

For instance, when the PtOx film of a thickness of about 20 nm is formed as the amorphous film 76a by a sputtering method, it is formed by using, for example, a sputtering device with the distance between the semiconductor substrate 61 and the target set about 60 mm under the conditions of a substrate temperature of about 350° C., a power of about 1 kW, and a growth time of 18 seconds in a mixture atmosphere in which Ar gas at a flow rate of about 36 sccm and oxygen (O₂) gas at a flow rate of about 144 sccm are supplied.

Further, for instance, when the IrOx film of a thickness of about 25 nm is formed as the amorphous film 76a by a sputtering method, it is formed by using, for example, a sputtering device with the distance between the semiconductor substrate 61 and the target set about 60 mm under the conditions of a substrate temperature of 150° C. or under (about 20° C., for instance), a power of about 1 kW, and a growth time of 12 seconds in a mixture atmosphere in which Ar gas at a flow rate of about 100 sccm and oxygen (O₂) gas at a flow rate of about 100 sccm are supplied.

Thereafter, the surface of the amorphous film 76a is plasma-processed in the atmosphere of NH₃ (ammonia) gas. The plasma processing using ammonia gas is the same as that used for processing the surface of the interlayer insulating film 71. The plasma processing using ammonia gas is conducted so that the distortion of the crystal generated in the TiN film 73 due to the flattening is completely eliminated, and an influence thereof does not extend to an Ir film 77a to be formed on the amorphous film 76a.

Next, as shown in FIG. 4B, the Ir film 77a of a thickness of about 100 nm is formed on the amorphous film 76a by a sputtering method under the conditions of a pressure of about 0.11 Pa (8.3×10⁻⁴ Torr), a substrate temperature of about 500° C., and a power of 0.5 kW in an Ar atmosphere, for example. The Ir film 77a is a film to be a lower electrode of the ferroelectric capacitor.

Next, as shown in FIG. 4C, heat treatment by RTA is conducted at a temperature of 650° C. or higher for a time of about 60 seconds in an atmosphere of Ar gas being an inert gas, for instance. This heat treatment enables to crystallize the amorphous film 76a to form a protective film 76 being self-oriented, and to improve, at the same time, the crystallinity of the Ir film 77a to be the lower electrode. By this heat treatment, the protective film 76 becomes a film in which at least a part thereof is crystallized and the other parts are in an amorphous state, or a film being completely crystallized from the amorphous state.

At this time, the protective film 76 is formed as a self-oriented film without being influenced by the lower layer films (oxidation preventing film 75 and the films therebelow) located under the protective film 76, which eliminates the dependency of the orientation of the lower electrode constituted of the Ir film 77a to be formed above the protective film on the crystallinity and the like of the W plugs 72b, thereby protecting the orientation of the lower electrode. In the present embodiment, for instance, the protective film 76 becomes a film whose crystal plane is oriented along a (111) plane.

Note that since the protective film 76 is formed by crystallizing the amorphous film 76a, it is formed by either of the conductive oxide film including at least any one kind out of PtOx, IrOx, RuOx, and PdOx, the conductive nitride film including at least any one kind out of TiN, TiAlN, TaN, and TaAlN, or the conductive oxynitride film including TiAlON. Further, each x in the conductive oxide film satisfies 1<x≦2.

Further, in the present embodiment, Ar gas is used to conduct the heat treatment by the RTA when forming the protective film 76, but, it is also possible to use gas containing N₂ or N₂O being an inert gas.

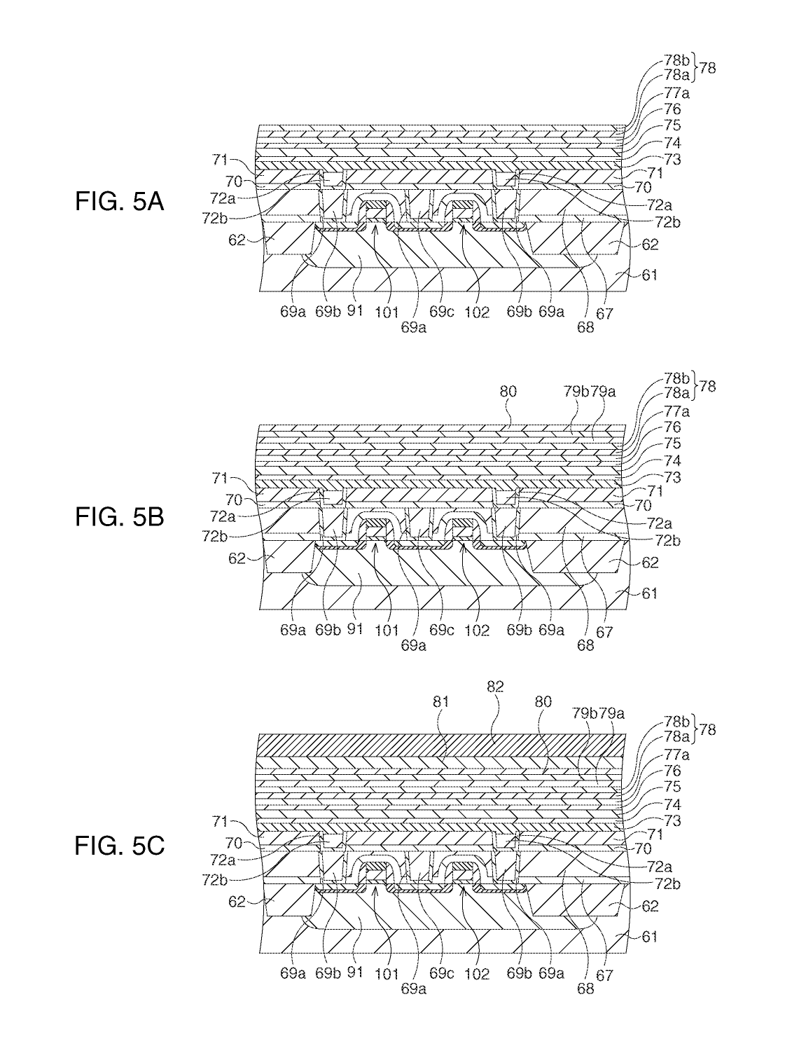

Next, as shown in FIG. 5A, a ferroelectric film 78 to be a capacitor film of the ferroelectric capacitor is formed on the Ir film 77a by an MO-CVD method. More specifically, the ferroelectric film 78 of the present embodiment is formed by a lead zirconate titanate (PZT: (Pb(Zr, Ti)O₃)) film having a two-layer structure, that is, a first PZT film 78a and a second PZT film 78b.

More specifically, first, Pb(DPM)₂, Zr(dmhd)₄ and Ti(O-iOr)₂(DPM)₂ are each dissolved into a THF (Tetra Hydro Furan: C₄H₈O) solvent at a concentration of about 0.3 mol/l, and a liquid raw material of each of Pb, Zr and Ti is formed. Further, these liquid raw materials are supplied into a vaporizer of an MO-CVD apparatus respectively at a flow rate of about 0.326 ml/minute, about 0.200 ml/minute and about 0.200 ml/minute, together with a THF solvent at a flow rate of about 0.474 ml/minute, and vaporized, and thereby, the raw material gas of Pb, Zr and Ti is formed.

Subsequently, in the MO-CVD apparatus, the raw material gas of Pb, Zr and Ti is supplied for about 620 seconds under the conditions of a pressure of about 665 Pa (5.0 Torr), and a substrate temperature of about 620° C., and thereby, the first PZT film 78a of a thickness of about 100 nm is formed on the Ir film 77a.

Subsequently, the second PZT film 78b in an amorphous state of a thickness of 1 nm to 30 nm, about 20 nm in the present embodiment, is formed on the entire surface by, for example, a sputtering method. Further, when the second PZT film 78b is formed by an MO-CVD method, as the organic source for supplying lead (Pb), a material formed by dissolving Pb(DPM)₂(Pb(C₁₁H₁₉O₂)₄) in a THF solution is used. Further, as the organic source for supplying zirconium (Zr), the material formed by dissolving Zr(DMHD)₄(Zr((C₉H₁₅O₂)₄) in a THF solution is used. Further, as the organic source for supplying titanium (Ti), the material formed by dissolving Ti(O-iPr)₂(DPM)₂(Ti (C₃H₇O)₂(C₁₁H₁₉O₂)₂) in a THF solution is used.

In the present embodiment, the ferroelectric film 78 is formed by an MO-CVD method and a sputtering method, but the present invention is not limited to this, and the ferroelectric film 78 can be formed by, for example, a sol-gel method, a metal-organic decomposition (MOD) method, a CSD (Chemical Solution Deposition) method, a chemical vapor deposition (CVD) method or an epitaxial growth method.

Next, as shown in FIG. 5B, an IrO_{X} film 79a, an IrO_{Y} film 79b and an Ir film 80 are sequentially formed on the second PZT film 78b. In this case, the IrO_{X} film 79a functions as a lower layer film of the upper electrode, and the IrO_{Y} film 79b functions as an upper layer film of the upper electrodes.

On formation of the IrO_{X} film 79a, first, an IrO_{X} film which is crystallized is formed with an thickness of about 50 nm at the time of deposition by a sputtering method. As the sputtering conditions on this occasion, the conditions under which oxidation of iridium occurs are set, for example, the deposition temperature is set at about 300° C., Ar and O₂ are used as deposition gas and Ar and O₂ are supplied each at a flow rate of about 100 sccm, and the power at the time of sputtering is set at about 1 kW to 2 kW.

Thereafter, heat treatment by RTA is performed for about 60 seconds in an atmosphere in which oxygen is supplied at a flow rate of about 20 sccm and Ar is supplied at a flow rate of about 2000 sccm at a temperature of about 725° C. The heat treatment completely crystallizes the ferroelectric film 78 (second PZT film 78b) to compensate oxygen deficiency and recovers a plasma damage of the IrO_{X} film 79a at the same time.

Subsequently, the IrO_{Y} film 79b is formed with a thickness of about 100 nm to 300 nm, more specifically, about 200 nm in the present embodiment on IrO_{X} film 79a by a sputtering method under the conditions of a pressure of about 0.8 Pa (6.0×10⁻³ Torr), a power of about 1.0 kW, and a deposition time of about 79 seconds in an Ar atmosphere, for example. In the present embodiment, in order to suppress deterioration in the process, the IrO_{Y} film 79b of the composition close to the stoichiometric composition of IrO₂ is applied to avoid occurrence of catalytic action for hydrogen. Thereby, the problem of the ferroelectric film 78 being reduced by hydrogen radicals is suppressed, and resistance against hydrogen of the ferroelectric capacitor is enhanced.

Subsequently, an Ir film 80 of a thickness of about 100 nm is formed on the IrO_{Y} film 79b by a sputtering method under the conditions of a pressure of about 1.0 Pa (7.5×10⁻³ Torr) and a power of about 1.0 kW in an Ar atmosphere, for example. The Ir film 80 functions as a hydrogen barrier film which prevents penetration of hydrogen, which occurs at the time of formation of wiring layers and the like, into the ferroelectric film 78. As the hydrogen barrier film, a Pt film and an SrRuO₃ film can be used other than this.

Next, after back surface cleaning of the semiconductor substrate 61 is performed, a TiN film 81 and a silicon oxide film 82 are sequentially formed on the Ir film 80, as shown in FIG. 5C. The TiN film 81 and the silicon oxide film 82 become hard masks at the time of formation of the ferroelectric capacitor.

Here, on formation of the TiN film 81, for example, a sputtering method is used. Further, on formation of the silicon oxide film 82, for example, a CVD method using TEOS gas is used.

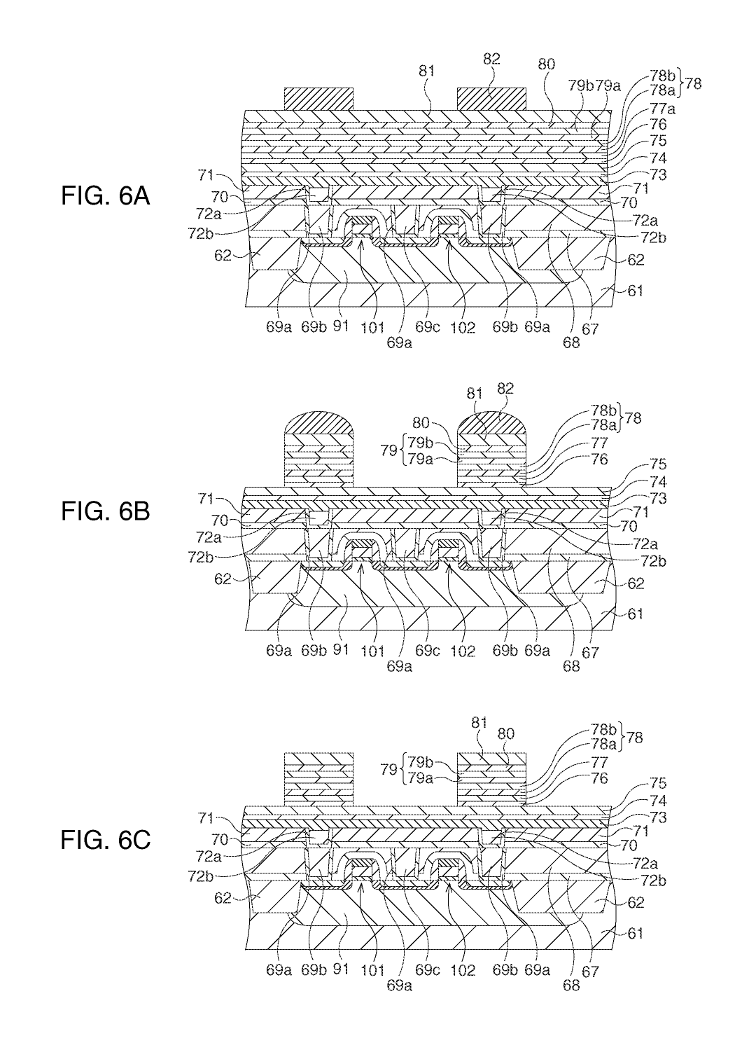

Next, as shown in FIG. 6A, the silicon oxide film 82 is patterned to cover only a ferroelectric capacitor formation region. Thereafter, the TiN film 81 is etched with the silicon oxide film 82 as a mask, and a hard mask constituted of the silicon oxide film 82 which covers only the ferroelectric capacitor formation region and the TiN film 81 is formed.

Next, as shown in FIG. 6B, the Ir film 80, the IrO_{Y} film 79b, the IrO_{X} film 79a, the second PZT film 78b, the first PZT film 78a, the Ir film 77a, and the protective film 76 in the region which is not covered with the hard mask are removed by plasma etching using mixture gas of HBr, O₂, Ar and C₄F₈ as etching gas. Thereby, the ferroelectric capacitor having the upper electrode 79 constituted of the IrO_{X} film 79a and the IrO_{Y} film 79b, the ferroelectric film 78 constituted of the first PZT film 78a and the second PZT film 78b, and the lower electrode 77 constituted of the Ir film 77a is formed.

In the present embodiment, the example of applying the iridium oxide film (IrO_{X} film and IrO_{Y} film) as the upper electrode 79 is shown, but the present invention is not limited to this, and a metal film made of at least any one kind of metal selected from the group consisting of Ir (iridium), ruthenium (Ru), platinum (Pt), rhodium (Rh), rhenium (Re), Osmium (Os) and palladium (Pd), or an oxide film thereof can be applied. For example, the upper electrode 79 may be formed by a film including a conductive oxide of SrRuO₃.

Further, as the ferroelectric film 78 of the ferroelectric capacitor, for example, a film in which the crystal structure becomes a Bi-layer structure (for example, one selected from (Bi₁₋ₓ-Rₓ)Ti₃O₁₂ (R is a rare earth element: 0<x<1), SrBi₂Ta₂O₉, and SrBi₄Ti₄O₁₅) or a perovskite structure because of the heat treatment can be formed. As such a ferroelectric film 78, in addition to the PZT film which is used in the present embodiment, a film expressed by a general formula ABO₂ such as PZT, SBT and BLT doped with a very small amount of at least any one of La, Ca, Sr and Si, and a Bi-layer compound can be applied. Further, in the present embodiment, a film made of a ferroelectric material is applied as the capacitor film, but, the present invention is not limited to this, and a film made of a high dielectric constant material can also be applied. In this case, it is possible to apply (Ba, Sr)TiO₃ or SrTiO₃ as the high dielectric constant material, for example.

Further, in the present embodiment, the example in which the Ir film is applied as the lower electrode 77 is shown, but the present invention is not limited to this, and a film including at least any one kind of metal out of Ir, Ru, Pt and Pd, or a film including an oxide in the one kind of metal can be applied. In this case, a metal of a platinum group such as Pt, or a conductive oxide such as PtO, IrO_{X} and SrRuO₃ is especially preferably used.

Next, as shown in FIG. 6C, the silicon oxide film 82 is removed by dry etching or wet etching.

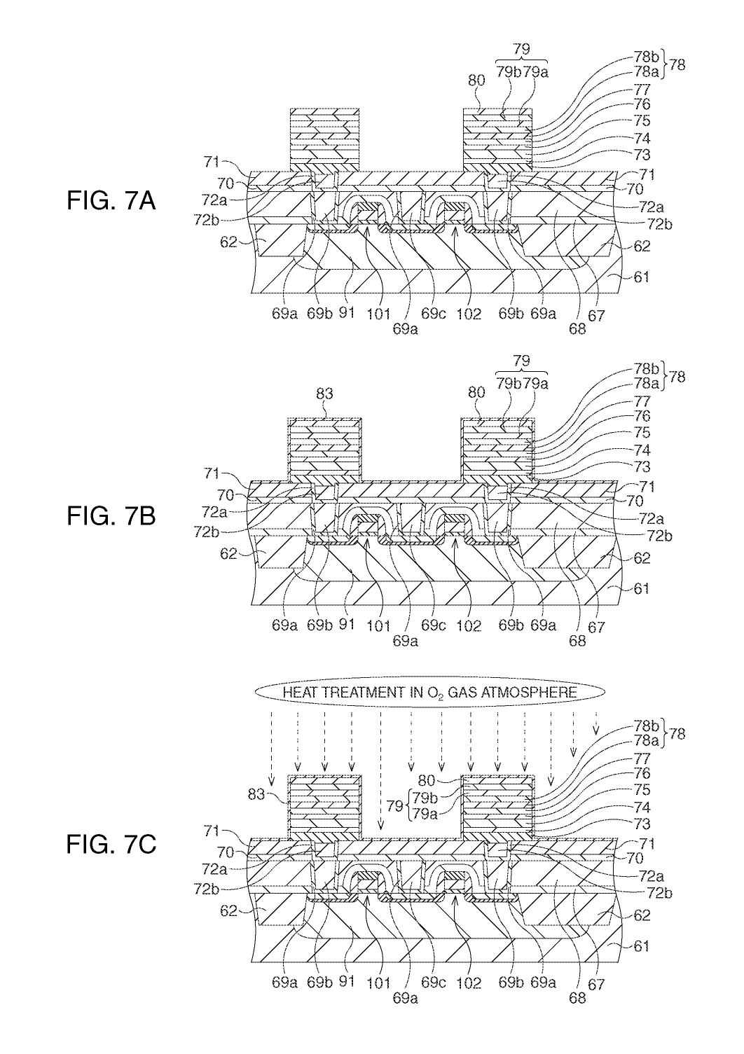

Next, by etching with the TiN film 81 as a mask, the oxidation preventing film 75, the Ti film 74 and the TiN film 73 in the region except for the ferroelectric capacitor formation regions are removed as shown in FIG. 7A. Thereafter, the TiN film 81 is removed.

Next, as shown in FIG. 7B, an Al₂O₃ film 83 of a thickness of about 20 nm is formed on the entire surface by a sputtering method.

Next, as shown in FIG. 7C, heat treatment is conducted in an atmosphere containing oxygen (O₂). This heat treatment is a recovery annealing performed for the purpose of recovering the damage of the ferroelectric film 78 of the ferroelectric capacitor. The condition of the recovery annealing is not particularly limited, but, in the present embodiment, this annealing is carried out at a substrate temperature of 550° C. to 700° C. When the ferroelectric film 78 is formed by PZT as in the present embodiment, recovery annealing for 60 minutes is desirably performed with the substrate temperature of about 650° C. in an atmosphere containing oxygen (O₂).

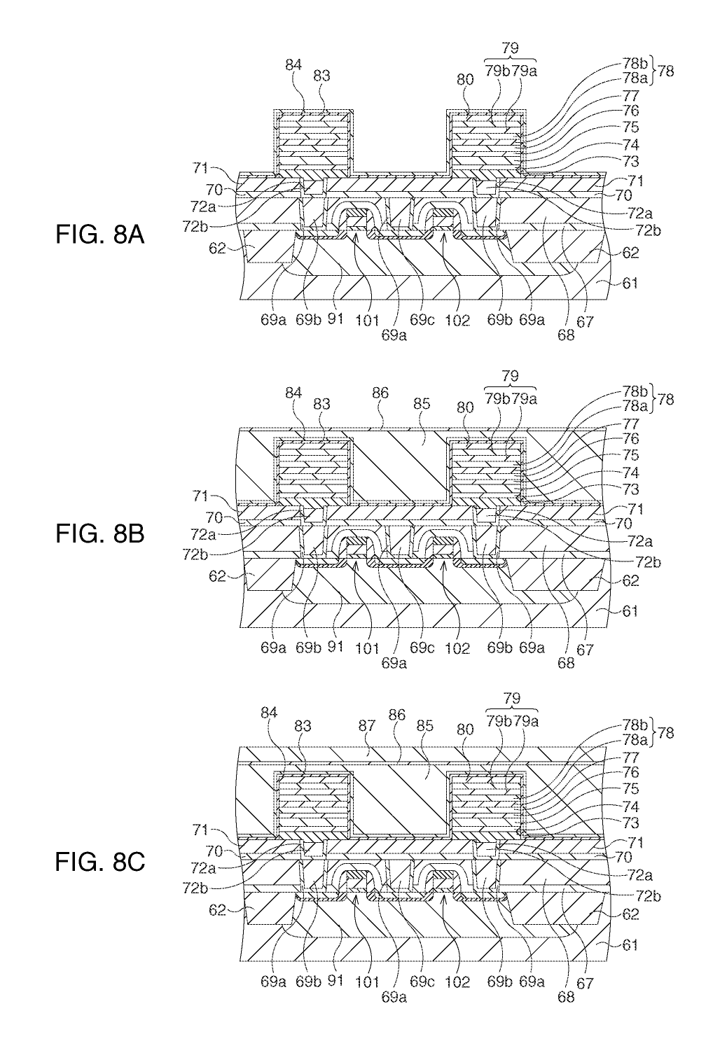

Next, as shown in FIG. 8A, an Al₂O₃ film 84 of a thickness of about 20 nm is formed on the entire surface by a CVD method.

Next, as shown in FIG. 8B, an interlayer insulating film 85 and an Al₂O₃ film 86 are sequentially formed on the Al₂O₃ film 84.

More specifically, first, a silicon oxide film of, for example, a thickness of about 1500 nm is deposited on the entire surface by a CVD method using, for example, plasma TEOS. Thereafter, the silicon oxide film is flattened by a CMP method and the interlayer insulating film 85 is formed.

Here, when the silicon oxide film is formed as the interlayer insulating film 85, mixture gas of, for example, TEOS gas, oxygen gas, and helium gas is used as raw material gas. As the interlayer insulating film 85, for example, an inorganic film or the like having insulating properties may be formed. After formation of the interlayer insulating film 85, heat treatment is performed in a plasma atmosphere which is generated by using N₂O gas, N₂ gas or the like. As a result of the heat treatment, moisture in the interlayer insulating film 85 is removed, the film quality of the interlayer insulating film 85 changes to make it difficult for water to penetrate into the interlayer insulating film 85.

Subsequently, an Al₂O₃ film 86 to be a barrier film is formed with a thickness of 20 nm to 100 nm on the interlayer insulating film 85, by, for example, a sputtering method or a CVD method. The Al₂O₃ film 86 is formed on the flattened interlayer insulating film 85, and therefore, is formed to be flat.

Next, as shown in FIG. 8C, a silicon oxide film is deposited on the entire surface by a CVD method using, for example, plasma TEOS, after which, the silicon oxide film is flattened by a CMP method, and an interlayer insulating film 87 of a thickness of 800 nm to 1000 nm is formed. As the interlayer insulating film 87, a SiON film, a silicon nitride film, or the like may be formed.

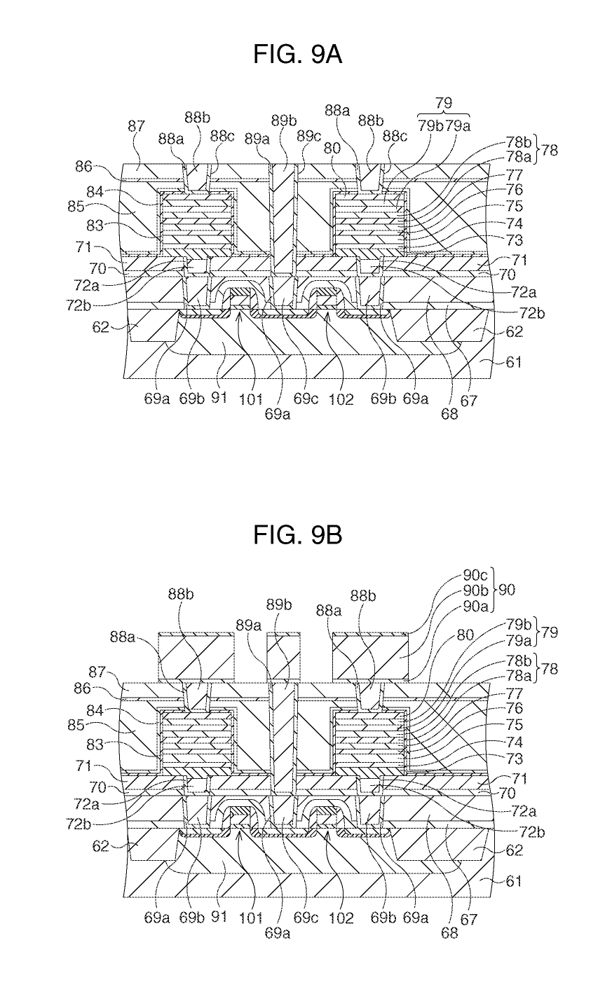

Next, as shown in FIG. 9A, glue films 88a, W plugs 88b, a glue film 89a and a W plug 89b are formed.

More specifically, first, via holes 88c for exposing the surface of the Ir film 80 which is the hydrogen barrier film in the ferroelectric capacitor are formed in the interlayer insulating film 87, the Al₂O₃ film 86, the interlayer insulating film 85, the Al₂O₃ film 84, and the Al₂O₃ film 83. Subsequently, heat treatment is performed in an oxygen atmosphere at a temperature of about 550° C., the oxygen deficiency which occurs in the ferroelectric film 78 with the formation of the via holes 88c is recovered.

Thereafter, a Ti film is deposited on the entire surface by, for example, a sputtering method, and subsequently, a TiN film is continuously deposited by an MO-CVD method. In this case, carbon has to be removed from the TiN film, and therefore, the processing in plasma of mixture gas of nitrogen and hydrogen is required, but, in the present embodiment, the Ir film 80 to be the hydrogen barrier film is formed in the ferroelectric capacitor, and therefore, the problem of hydrogen penetrating into the ferroelectric film 78 and reducing the ferroelectric film 78 does not occur.

Subsequently, after a W film with a thickness sufficient to fill the via holes 88c is deposited by a CVD method, the W film, the TiN film and the Ti film are polished by a CMP method until the surface of the interlayer insulating film 87 is exposed to perform flattening, and thereby, the glue films 88a each constituted of the Ti film and the TiN film, and the W plugs 88b are formed in the via holes 88c.

Subsequently, via holes 89c for exposing the surface of the W plug 69c are formed in the interlayer insulating film 87, the Al₂O₃ film 86, the interlayer insulating film 85, the Al₂O₃ film 84, the Al₂O₃ film 83, the interlayer insulating film 71, and the silicon oxynitride film 70. Subsequently, a TiN film is deposited on the entire surface by, for example, a sputtering method. Thereafter, a W film with a thickness sufficient to fill the via holes 89c is deposited, and thereafter, the W film and the TiN film are polished until the surface of the interlayer insulating film 87 is exposed by a CMP method to perform flattening, whereby the glue film 89a constituted of the TiN film and the W plug 89b are formed in the via holes 89c. The glue film 89a can be formed as the film constituted of a stacked film of a Ti film and a TiN film by depositing the Ti film by, for example, a sputtering method, and by subsequently depositing the TiN film continuously by a MO-CVD method.

Next, as shown in FIG. 9B, a metal wiring layer 90 is formed.

More specifically, first, a Ti film of a thickness of about 60 nm, a TiN film of a thickness of about 30 nm, an AlCu alloy film of a thickness of about 360 nm, a Ti film of a thickness of about 5 nm, and a TiN film of a thickness of about 70 nm are sequentially stacked on the entire surface by, for example, a sputtering method.

Subsequently, by using a photolithography technique, the stacked film is patterned into a predetermined shape, and the metal wiring layer 90 constituted of a glue film 90a constituted of the Ti film and the TiN film, a wiring film 90b constituted of the AlCu alloy film, and a glue film 90c constituted of the Ti film and the TiN film is formed on each of the W plugs 88b and 89b.

Subsequently, after formation of an interlayer insulating film and formation of a contact plug are further performed, metal wiring layers on and after the second layer are formed, a cover film constituted of, for example, a silicon oxide film and a silicon oxynitride film is further formed, and the ferroelectric memory according to the present embodiment including the ferroelectric capacitor having the lower electrode 77, the ferroelectric film 78 and the upper electrode 79 is completed.

According to the ferroelectric memory relating to the embodiment, since the protective film 76 which is made to be self-oriented by being deposited in an amorphous state and heat-processed, and is made of at least any one kind out of a conductive oxide, a conductive nitride, and a conductive oxynitride is provided right below the lower electrode 77, it is possible to prevent the orientation of the lower electrode 77 from depending on the lower layer films located below the protective film 76, resulting that the orientation of the lower electrode 77 can be made uniform. Accordingly, the orientation of the ferroelectric film 78 to be formed on the lower electrode 77 can be made uniform, which enables to enhance an electric characteristic (characteristic of electric charge amount of remnant polarization of the ferroelectric film 78, for instance) of the ferroelectric capacitor, and to improve the yield of a device.

Further, the protective film 76 is formed by being deposited in an amorphous state, so that even when the crystal of the TiN film 73 is distorted by the polishing of the CMP method with respect to the TiN film 73, it is possible to make the influence thereof hardly reach the lower electrode 77, resulting that the orientation of the lower electrode 77 can be maintained in a good condition. Further, since the surface of the amorphous film 76a is plasma-processed in an atmosphere of NH₃ (ammonia) gas, it is possible to completely eliminate the distortion of the crystal generated in the TiN film 73 because of the flattening, and to prevent the influence thereof from reaching the lower electrode 77 to be formed on the amorphous film 76a.

### MODIFIED EXAMPLES

Hereinafter, various modified examples according to the embodiment will be described.

Concerning the respective modified examples shown as follows, the same constituent members and the like as those disclosed in the embodiment are assigned with the same reference numerals and characters, and since the manufacturing methods of the constituent members and the like are the same as those disclosed in the embodiment, the detailed explanation of the manufacturing methods will be omitted.

### Modified Example 1

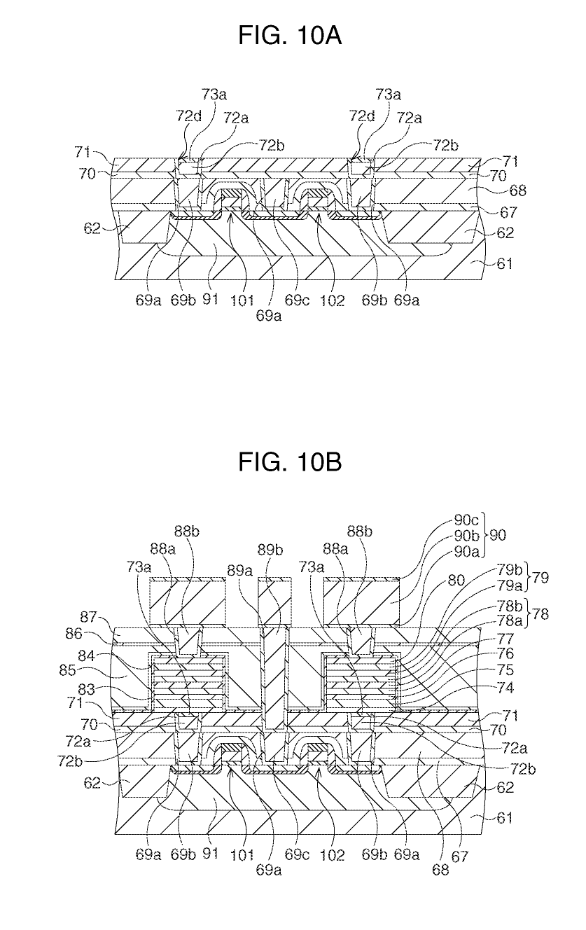

FIG. 10A and FIG. 10B are schematic sectional views showing a manufacturing method of a ferroelectric memory (semiconductor device) according to a modified example 1 of the embodiment.

In the modified example 1, the glue film 72a and the W plugs 72b are formed in the via holes 72c first through each of the steps of FIG. 2A to FIG. 2C and FIG. 3A. On this occasion, recesses 72d are formed in the W plugs 72b.

Next, as shown in FIG. 10A, TiN films 73a are formed to fill the recesses 72d.

More specifically, first, plasma processing is applied to the surface of the interlayer insulating film 71 in NH₃ (ammonia) gas atmosphere to cause NH groups to bond to the oxygen atoms on the surface of the interlayer insulating film 71. Subsequently, a Ti film of a thickness of about 100 nm is formed on the entire surface by, for example, a sputtering method. Thereafter, by applying heat treatment by RTA at a temperature of about 650° C. for a time of about 60 seconds to the Ti film in a nitrogen atmosphere, a TiN film of a thickness of about 100 nm to be a base conductive film is formed. The base conductive film is not limited to a TiN film, and, for example, a TiAlN film, a tungsten (W) film, a silicon (SiO₂) film and a copper (Cu) film can be used as the base conductive film.

In this state, in the TiN film, recessed portions are formed on its top surface by reflecting the recesses 72d, and this becomes the factor of degradation of crystallinity of the ferroelectric film which is formed above the TiN film (the orientation of the ferroelectric film becomes non-uniform).

Thus, in this example, by performing flattening by polishing the TiN film until the surface of the interlayer insulating film 71 is exposed by a CMP method, the recessed portion formed on the TiN film is removed, and a TiN film 73a which fills the recesses 72d is formed.

Next, after the Ti film 74 shown in FIG. 3C is formed on the entire surface, each of the steps in FIG. 4A to FIG. 9B is carried out, and thereby, the ferroelectric memory according to the modified example 1 shown in FIG. 10B is completed.

According to the ferroelectric memory relating to the modified example 1, the same effect as the ferroelectric memory according to the above-described embodiment can be provided.

### Modified Example 2

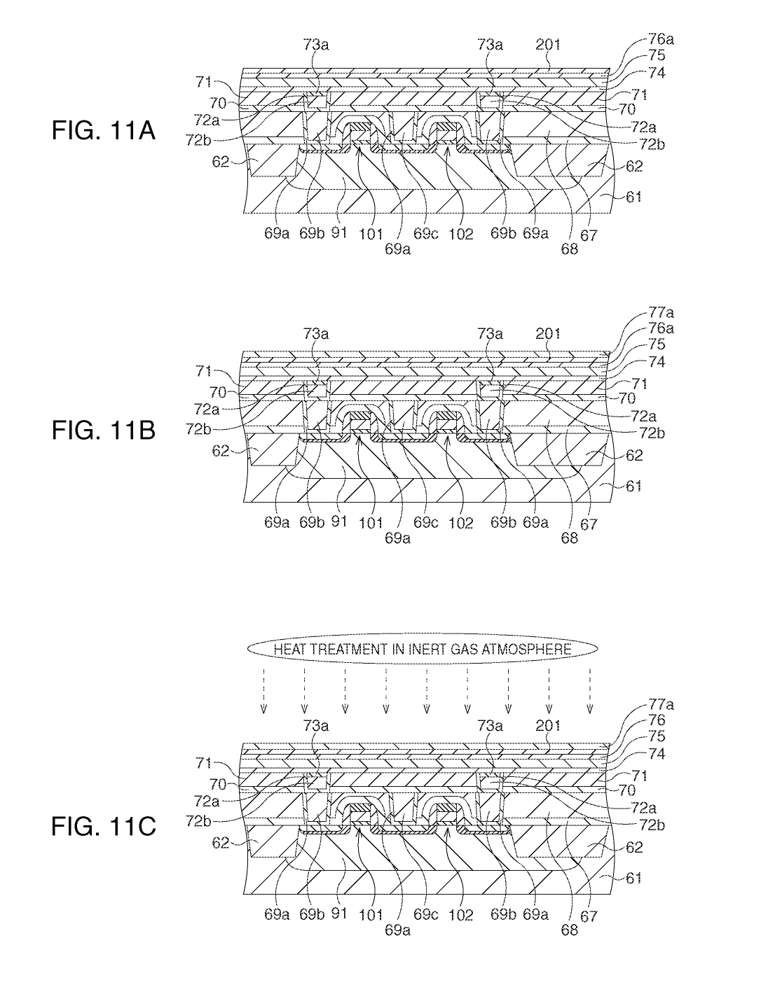

FIG. 11A to FIG. 16B are schematic sectional views showing a manufacturing method of a ferroelectric memory (semiconductor device) according to a modified example 2 of the embodiment.

In the modified example 2, the oxidation preventing film 75 and the amorphous film 76a are formed on the Ti film 74 through each of the steps of FIG. 2A to FIG. 2C, FIG. 3A, FIG. 10A, FIG. 3C, and FIG. 4A.

Next, as shown in FIG. 11A, a conductive adhesive film 201 is formed on the amorphous film 76a. This conductive adhesive film 201 has a function for further improving the crystallinity of the lower electrode to be formed an upper layer thereof.

In this example, a Ti film of a thickness of about 10 nm is formed as the conductive adhesive film 201 using, for example, a sputtering method. In this case, by using, for example, a sputtering device with the distance between the semiconductor substrate 61 and the target set about 60 mm, a Ti film whose crystal plane is strongly oriented along a (002) plane is formed by a sputtering method under the conditions of a substrate temperature of about 20° C., a power of about 1 kW, and a growth time of 6 seconds in an atmosphere of Ar gas.

Note that in this example, the example in which the Ti film is applied as the conductive adhesive film 201 is shown, but, the present invention is not limited to this, and any films can be applied as long as they include at least any one kind out of, for example, Ti, Pt, Ir, Re, Ru, Pd, and Os.

Next, as shown in FIG. 11B, the Ir film 77a of a thickness of about 100 nm is formed on the conductive adhesive film 201 by, for example, a sputtering method. The Ir film 77a is a film to be a lower electrode of the ferroelectric capacitor.

Next, as shown in FIG. 11C, heat treatment by RTA is conducted at a temperature of 650° C. or higher for a time of about 60 seconds in an atmosphere of Ar gas being an inert gas, for instance. This heat treatment enables to crystallize the amorphous film 76a to form the protective film 76 being self-oriented, and to improve, at the same time, the crystallinity of the Ir film 77a to be the lower electrode. By this heat treatment, the protective film 76 becomes a film in which at least a part thereof is crystallized and the other parts are in an amorphous state, or a film completely crystallized from the amorphous state.

At this time, the protective film 76 is formed as a self-oriented film without being influenced by its lower layer film (oxidation preventing film 75) and the films therebelow, which eliminates the dependency of the orientation of the lower electrode constituted of the Ir film 77a to be formed above the protective film on the crystallinity and the like of the W plugs 72b, thereby protecting the orientation of the lower electrode. In the present embodiment, the protective film 76 becomes a film whose crystal plane is oriented along a (111) plane.

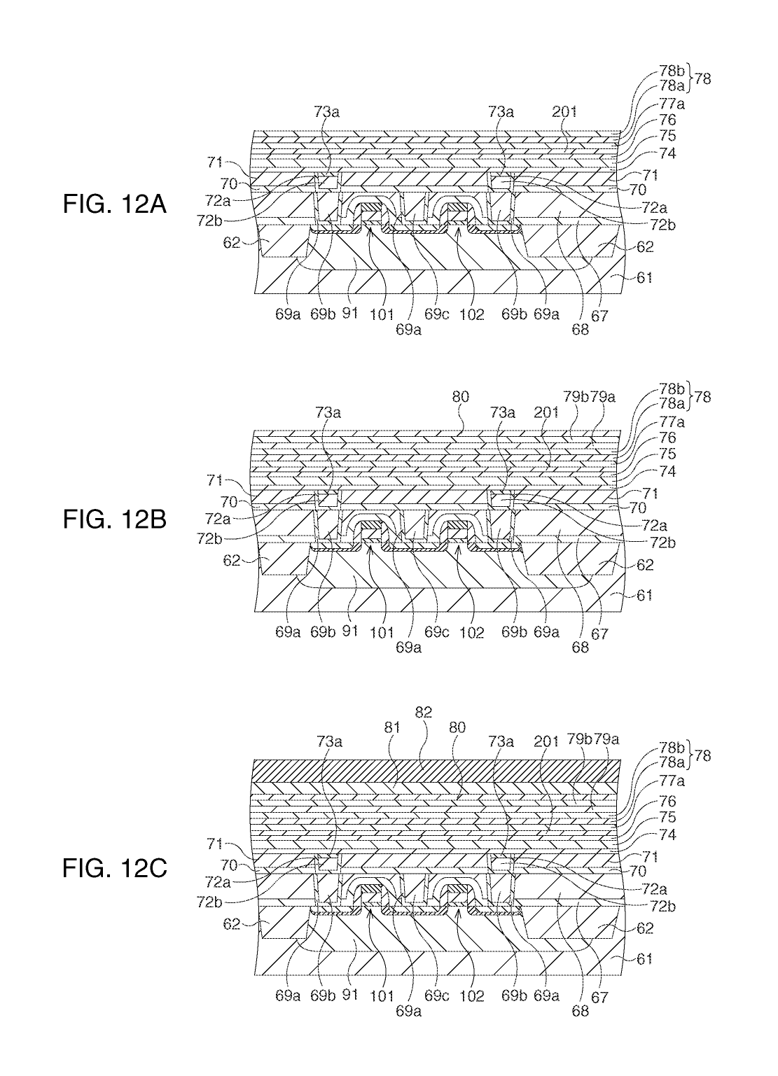

Next, as shown in FIG. 12A, a ferroelectric film 78 to be a capacitor film of the ferroelectric capacitor is formed on the Ir film 77a by an MO-CVD method. More specifically, the ferroelectric film 78 of the present embodiment is formed by a PZT film having a two-layer structure (the first PZT film 78a and the second PZT film 78b).

Next, as shown in FIG. 12B, the IrO_{X} film 79a, the IrO_{Y} film 79b and the Ir film 80 are sequentially formed on the second PZT film 78b.

Next, after back surface cleaning of the semiconductor substrate 61 is performed, the TiN film 81 and the silicon oxide film 82 are sequentially formed on the Ir film 80, as shown in FIG. 12C.

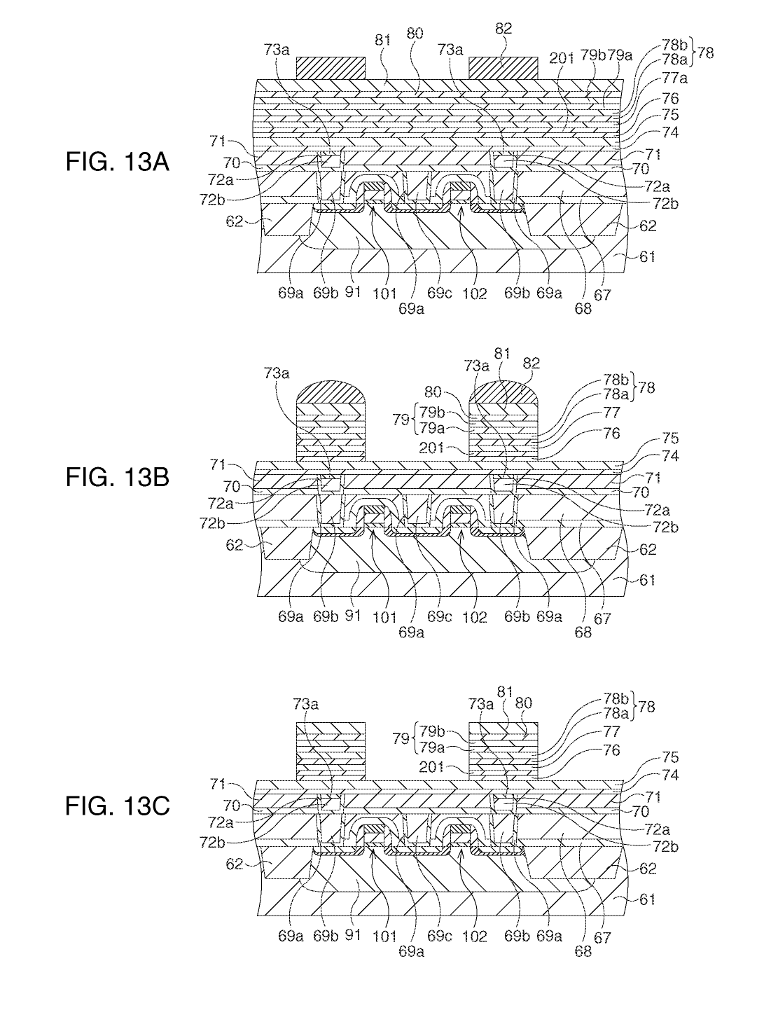

Next, as shown in FIG. 13A, the silicon oxide film 82 is patterned to cover only the ferroelectric capacitor formation region. Thereafter, the TiN film 81 is etched with the silicon oxide film 82 as a mask, and a hard mask constituted of the silicon oxide film 82 which covers only the ferroelectric capacitor formation region and the TiN film 81 is formed.

Next, as shown in FIG. 13B, the Ir film 80, the IrO_{Y} film 79b, the IrO_{X} film 79a, the second PZT film 78b, the first PZT film 78a, the Ir film 77a, the conductive adhesive film 201, and the protective film 76 in the region which is not covered with the hard mask are removed by plasma etching using mixture gas of HBr, O₂, Ar and C₄F₈ as etching gas. Thereby, the ferroelectric capacitor having the upper electrode 79 constituted of the IrO_{X} film 79a and the IrO_{Y} film 79b, the ferroelectric film 78 constituted of the first PZT film 78a and the second PZT film 78b, and the lower electrode 77 constituted of the Ir film 77a is formed.

Next, as shown in FIG. 13C, the silicon oxide film 82 is removed by dry etching or wet etching.

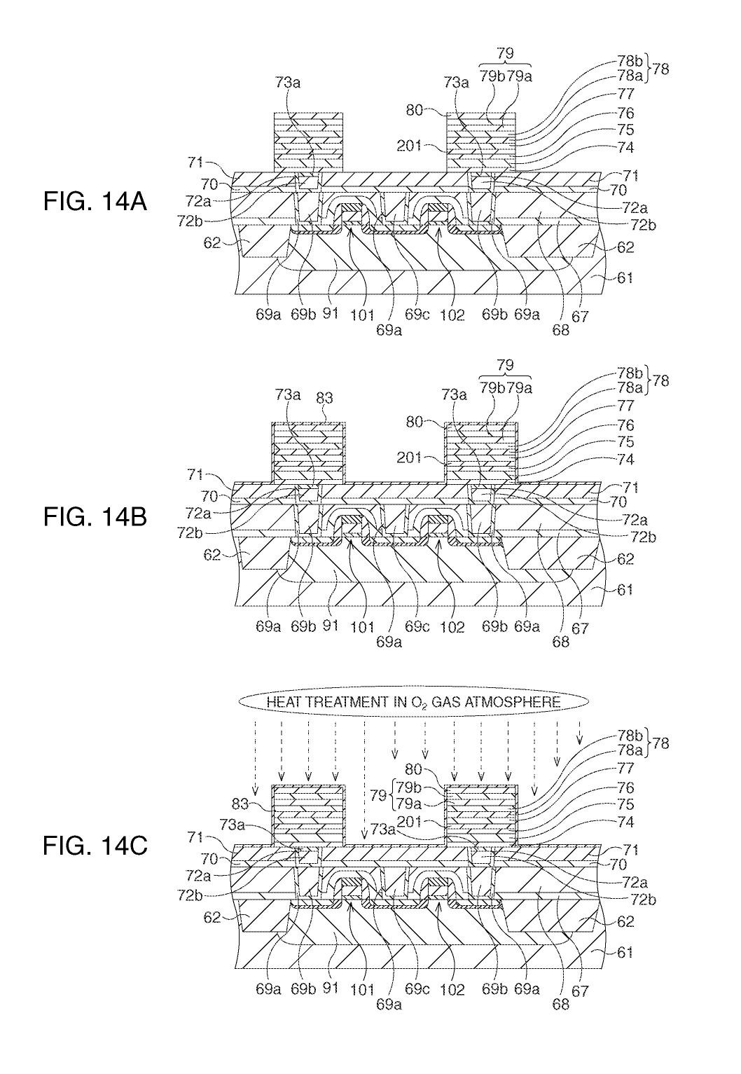

Next, by etching with the TiN film 81 as a mask, the oxidation preventing film 75 and the Ti film 74 in the region except for the ferroelectric capacitor formation regions are removed as shown in FIG. 14A. Thereafter, the TiN film 81 is removed.

Next, as shown in FIG. 14B, the Al₂O₃ film 83 of a thickness of about 20 nm is formed on the entire surface by a sputtering method.

Next, as shown in FIG. 14C, heat treatment is conducted in an atmosphere containing oxygen (O₂), thereby recovering the damage of the ferroelectric film 78 of the ferroelectric capacitor.

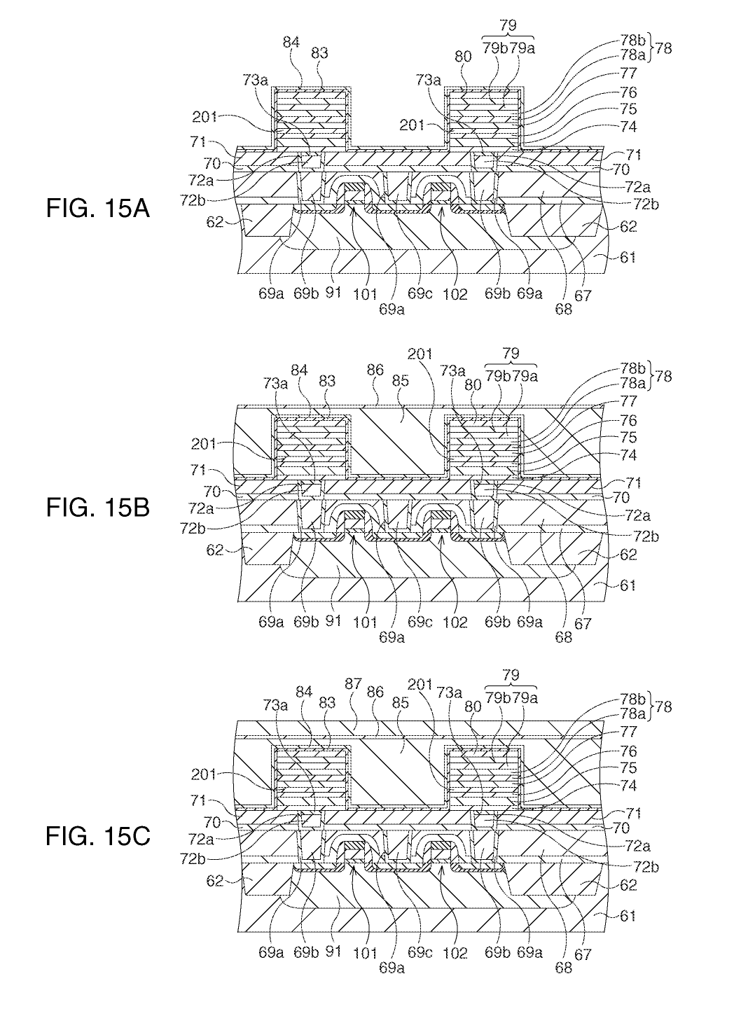

Next, as shown in FIG. 15A, the Al₂O₃ film 84 of a thickness of about 20 nm is formed on the entire surface by a CVD method.

Next, as shown in FIG. 15B, the interlayer insulating film 85 and the Al₂O₃ film 86 are sequentially formed on the Al₂O₃ film 84.

Next, as shown in FIG. 15C, a silicon oxide film is deposited on the entire surface by a CVD method using, for example, plasma TEOS, after which, the silicon oxide film is flattened by a CMP method, and the interlayer insulating film 87 of a thickness of 800 nm to 1000 nm is formed.

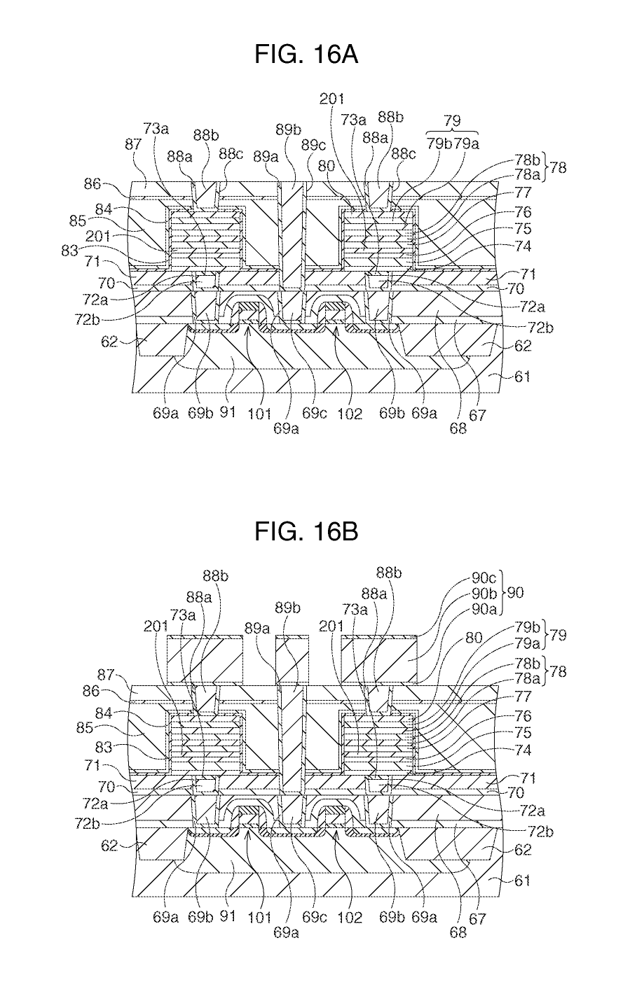

Next, as shown in FIG. 16A, the glue films 88a, the W plugs 88b, the glue film 89a and the W plug 89b are formed.

More specifically, first, the via holes 88c for exposing the surface of the Ir film 80 are formed in the interlayer insulating film 87, the Al₂O₃ film 86, the interlayer insulating film 85, the Al₂O₃ film 84, and the Al₂O₃ film 83. Subsequently, heat treatment is performed in an oxygen atmosphere at a temperature of about 550° C., the oxygen deficiency which occurs in the ferroelectric film 78 with the formation of the via holes 88c is recovered.

Thereafter, a Ti film is deposited on the entire surface by, for example, a sputtering method, and subsequently, a TiN film is continuously deposited by an MO-CVD method. Subsequently, after a W film with a thickness sufficient to fill the via holes 88c is deposited by a CVD method, the W film, the TiN film and the Ti film are polished by a CMP method until the surface of the interlayer insulating film 87 is exposed to perform flattening, and thereby, the glue films 88a each constituted of the Ti film and the TiN film, and the W plugs 88b are formed in the via holes 88c.

Subsequently, the via holes 89c for exposing the surface of the W plug 69c are formed in the interlayer insulating film 87, the Al₂O₃ film 86, the interlayer insulating film 85, the Al₂O₃ film 84, the Al₂O₃ film 83, the interlayer insulating film 71, and the silicon oxynitride film 70. Subsequently, a TiN film is deposited on the entire surface by, for example, a sputtering method. Thereafter, a W film with a thickness sufficient to fill the via holes 89c is deposited, and thereafter, the W film and the TiN film are polished until the surface of the interlayer insulating film 87 is exposed by a CMP method to perform flattening, whereby the glue film 89a constituted of the TiN film and the W plug 89b are formed in the via holes 89c.

Next, as shown in FIG. 16B, the metal wiring layer 90 is formed.

More specifically, first, a Ti film of a thickness of about 60 nm, a TiN film of a thickness of about 30 nm, an AlCu alloy film of a thickness of about 360 nm, a Ti film of a thickness of about 5 nm, and a TiN film of a thickness of about 70 nm are sequentially stacked on the entire surface by, for example, a sputtering method.

Subsequently, by using a photolithography technique, the stacked film is patterned into a predetermined shape, and the metal wiring layer 90 constituted of the glue film 90a constituted of the Ti film and the TiN film, the wiring film 90b constituted of the AlCu alloy film, and the glue film 90c constituted of the Ti film and the TiN film is formed on each of the W plugs 88b and 89b.

Subsequently, after formation of an interlayer insulating film and formation of a contact plug are further performed, metal wiring layers on and after the second layer are formed, a cover film constituted of, for example, a silicon oxide film and a silicon oxynitride film is further formed, and the ferroelectric memory according to the modified example 2 including the ferroelectric capacitor having the lower electrode 77, the ferroelectric film 78 and the upper electrode 79 is completed.

According to the ferroelectric memory relating to the modified example 2, since the conductive adhesive film 201 for the lower electrode 77 is provided between the lower electrode 77 and the protective film 76, it is possible to further improve the crystallinity of the lower electrode 77 in addition to obtaining the effect of the ferroelectric memory relating to the aforementioned embodiment. Accordingly, it is possible to further improve the crystallinity of the ferroelectric film 78 formed on the lower electrode 77.

—Test Results—

In order to confirm the effect of the ferroelectric memory according to the embodiment, an evaluation of the crystallinity of the ferroelectric film was conducted. At this time, by comparing with a ferroelectric memory according to a comparative example shown below, the evaluation of the crystallinity of the ferroelectric film was performed.

As a ferroelectric memory according to the embodiment, the ferroelectric memory shown in FIG. 9B was applied in which an IrOx film of a thickness of about 25 nm was formed as the protective film 76 to be formed on the oxidation preventing film 75. On the other hand, as a ferroelectric memory according to the comparative example, the one in which the lower electrode 77 is formed directly on the oxidation preventing film 75 without providing the protective film 76 was applied. Subsequently, the crystallinity of the ferroelectric film (PZT film) 78 of each test sample was measured.

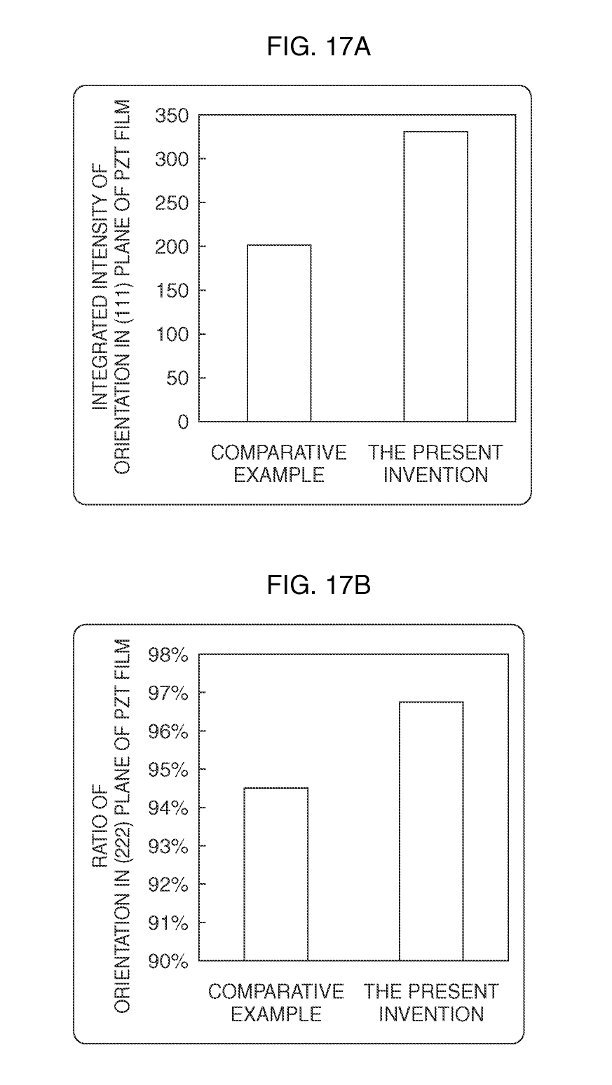

FIG. 17A is a characteristic diagram showing an integrated intensity of orientation in a crystal plane (111) of the ferroelectric film (PZT film) of the ferroelectric memory according to the embodiment and that of the ferroelectric memory according to the comparative example. Further, FIG. 17B is a characteristic diagram showing a ratio of orientation in a crystal plane (222) of the ferroelectric film (PZT film) of the ferroelectric memory according to the embodiment and that of the ferroelectric memory according to the comparative example. The crystal plane (222) is a plane having the same orientation as that of the crystal plane (111), and the ratio of orientation in the crystal plane (222) is represented by (integrated intensity of (222)/[(100)+(101)+(222)]).

As shown in FIG. 17A, in the ferroelectric memory according to the embodiment, the ferroelectric film (PZT film) being oriented along the crystal plane (111) stronger than that of the ferroelectric memory according to the comparative example was obtained. This indicates that the ferroelectric memory according to the embodiment has the ferroelectric film (PZT film) whose orientation is more uniform than that of the ferroelectric memory according to the comparative example. Further, as confirmed from the result shown in FIG. 17B, in the ferroelectric memory according to the embodiment, the ferroelectric film is oriented almost along the (111) plane.

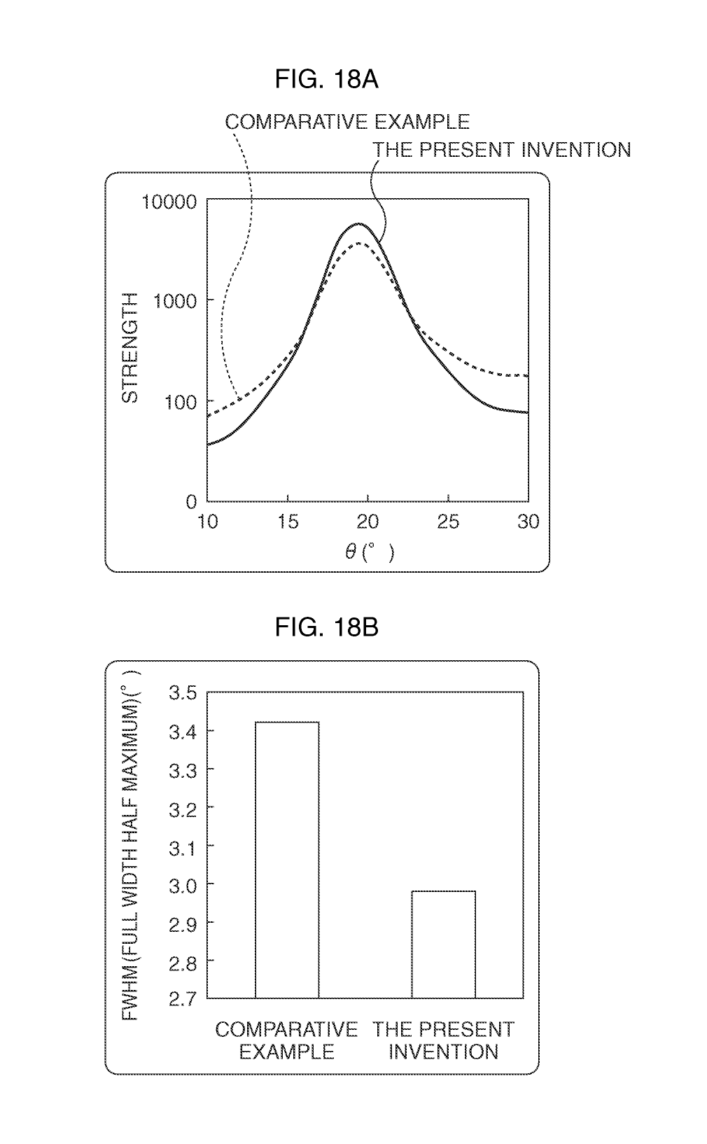

FIG. 18A is a characteristic diagram of a rocking curve in the crystal plane (111) of the ferroelectric film (PZT film) of the ferroelectric memory according to the embodiment and that of the ferroelectric memory according to the comparative example. Further, FIG. 18B is a characteristic diagram of a FWHM of the rocking curve in the crystal plane (111) of the ferroelectric film (PZT film) of the ferroelectric memory according to the embodiment and that of the ferroelectric memory according to the comparative example.

From the results shown in FIG. 18A and FIG. 18B, it was proved that the ferroelectric memory according to the embodiment has an orientation strength in the crystal plane (111) of the ferroelectric film (PZT film) stronger than that of the ferroelectric memory according to the comparative example, and since the FWHM of the rocking curve becomes small, the crystallinity of the ferroelectric film (PZT film) is further enhanced.

All examples and conditional language recited herein are intended for pedagogical purposes to aid the reader in understanding the principles of the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

### INDUSTRIAL APPLICABILITY

According to the present invention, it becomes possible to make an orientation of a capacitor film uniform, and to improve an electric characteristic of a capacitor.

What is claimed is:

1. A manufacturing method of a semiconductor device, comprising:
forming an insulating film above a semiconductor substrate;
forming a hole penetrating the insulating film;
forming a conductive plug in the hole so that the position of the top surface of the conductive plug is lower than the position of the top surface of the insulating film;
forming a conductive film flattened at least above the conductive plug so that the position of the top surface of the conductive film is higher than the position of the top surface of the insulating film;
forming a capacitor comprising a lower electrode, a capacitor film formed above the lower electrode and an upper electrode formed above the capacitor film, above the conductive film,
wherein the formation of the capacitor, comprising
forming a protective film between the conductive film and the lower electrode, and
the formation of the protective film, comprising
forming an amorphous film being made of at least any one kind out of a conductive oxide, a conductive nitride, and a conductive oxynitride above the conductive film; and
crystallizing at least a part of the amorphous film so that the amorphous film is made to be self-oriented, by performing thermal treatment after a lower electrode film to be the lower electrode is formed above the amorphous film.

2. The manufacturing method of the semiconductor device according to claim 1,
wherein the formation of the protective film, further comprising performing plasma processing, after forming the amorphous film, on an upper surface of the amorphous film in an atmosphere of gas containing nitrogen.

3. The manufacturing method of the semiconductor device according to claim 1,
wherein the protective film is a film including at least any one kind out of PtOx (platinum oxide), IrOx (iridium oxide), RuOx (ruthenium oxide), PdOx (palladium oxide), TiN (titanium nitride), TiAlN (titanium-aluminum nitride), TiAlON (titanium-aluminum oxynitride), TaN (tantalum nitride), and TaAlN (tantalum-aluminum nitride), and wherein each x satisfies 1<x≦2.
